(19) United States
(12) Patent Application Publication
(10) Pub. No.: US 2012/0139058 A1
(43) Pub. Date: Jun. 7, 2012

(54) POWER MOS DEVICE

(76) Inventors: Tse-Lung Yang, Yunlin County (TW); Hsiang-Chung Chang, Hsinchu City (TW)

(21) Appl. No.: 12/982,898

(22) Filed: Dec. 31, 2010

(30) Foreign Application Priority Data
Dec. 2, 2010 (TW) 099141896

(51) Int. Cl. H01L 27/088

(52) U.S. Cl. 257/401; 257/E27.06

(57) ABSTRACT

A power MOS device having a gate with crosshatched lattice pattern on a substrate and at lease a source or a drain isolated by the gate, characterized in that the source has only one diffusion region of a pre-selected conductivity type. According to one embodiment, the source has a source diffusion of first conductivity type and the drain has a drain diffusion of first conductivity type. The source diffusion is replaced with substrate contact diffusion at some source sites across the transistor array.

### BACKGROUND OF THE INVENTION

1. Field of the Invention

The present invention relates generally to the field of power devices. More particularly, the present invention relates to an improved layout and structure of a power metal-oxide-semiconductor (MOS) device.

2. Description of the Prior Art

As known in the art, power MOS devices are widely used in various technical fields, for example, power switch of power management applications, driving circuit of display devices and motor electronics. It is also well known that the prior art power MOS device is typically laid out to have an interdigitated finger-type gate pattern or a waffle-shaped gate pattern.

Conventionally, the prior art multiple finger layout requires substrate contact lines in the transistor cell array. Therefore, the prior art multiple finger layout occupies more chip area and is difficult to shrink device size. An exemplary prior art waffle-shaped layout of the power MOS device is shown in FIG. 1. The gate 12 is laid out to have a crosshatched lattice pattern separating source regions 14 and drain regions 16 from one another. The substrate contact 20 is disposed at each of the source regions 14. The source regions 14 are connected together via a source metal connection layer such as the first metal layer or metal-1, while the drain regions 16 are connected together via an upper metal connection layer such as the second metal layer or metal-2, which is connected to the underlying drain regions through respective apertures formed in the metal-1. Compared to the prior art multiple finger layout, the waffle-shaped layout of the power MOS device has advantages such as larger effective gate width and thus lower R_{DS(ON)}.

However, the above-described waffle-shaped layout of the power MOS device still has drawbacks. For example, the substrate contact element or plug 20, which directly contacts with the substrate contact doping region, at each of the source regions is typically surrounded by four source contact elements or plugs 14a. This limits the miniaturization of the each of the source regions or drain regions, and the amount of the transistors per unit area of the transistor array is difficult to increase.

### SUMMARY OF THE INVENTION

It is therefore one objective of the present invention to provide an improved layout and structure of a power MOS device in order to solve the above-described prior art problems or shortcomings.

According to one aspect of the invention, a power MOS device comprises a substrate, a gate with crosshatched lattice pattern on a substrate, and at lease a source region and a drain region separated from each other by the gate, characterized in that the source region has only one diffusion region of a pre-selected conductivity type. According to one embodiment, the source region has a source diffusion region of first conductivity type and the drain region has a drain diffusion region of first conductivity type. The source diffusion region is replaced with substrate contact diffusion region at some source sites across the transistor array.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a layout diagram illustrating a conventional waffle-type power MOS device.

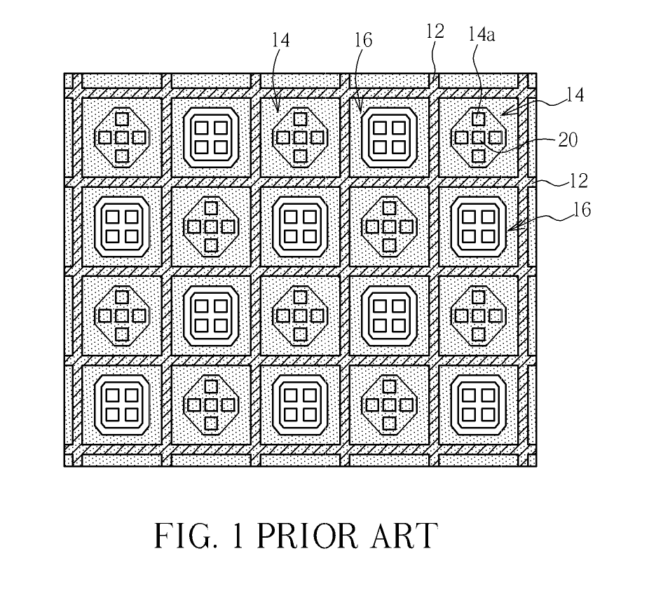

FIG. 2 is a partial layout diagram showing a waffle-type power MOS device in accordance with one embodiment of this invention.

FIG. 3 is a sectional view taken alone line I-I′ in FIG. 2.

FIG. 4 is a sectional view taken alone line II-II′ in FIG. 2.

### DETAILED DESCRIPTION

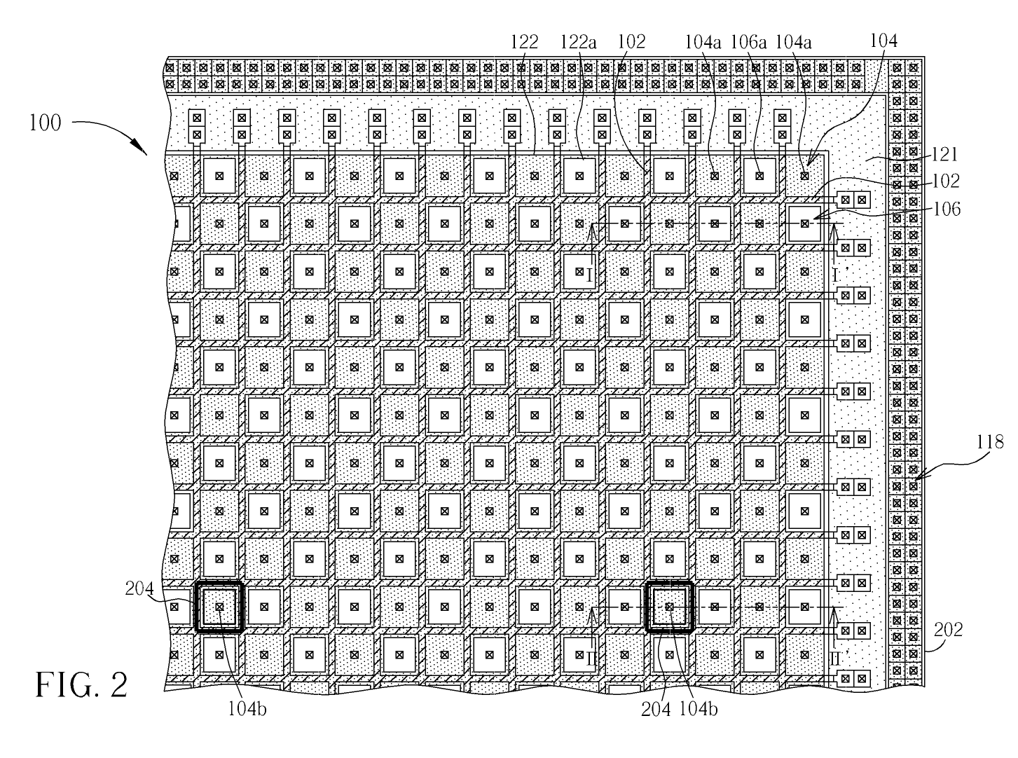

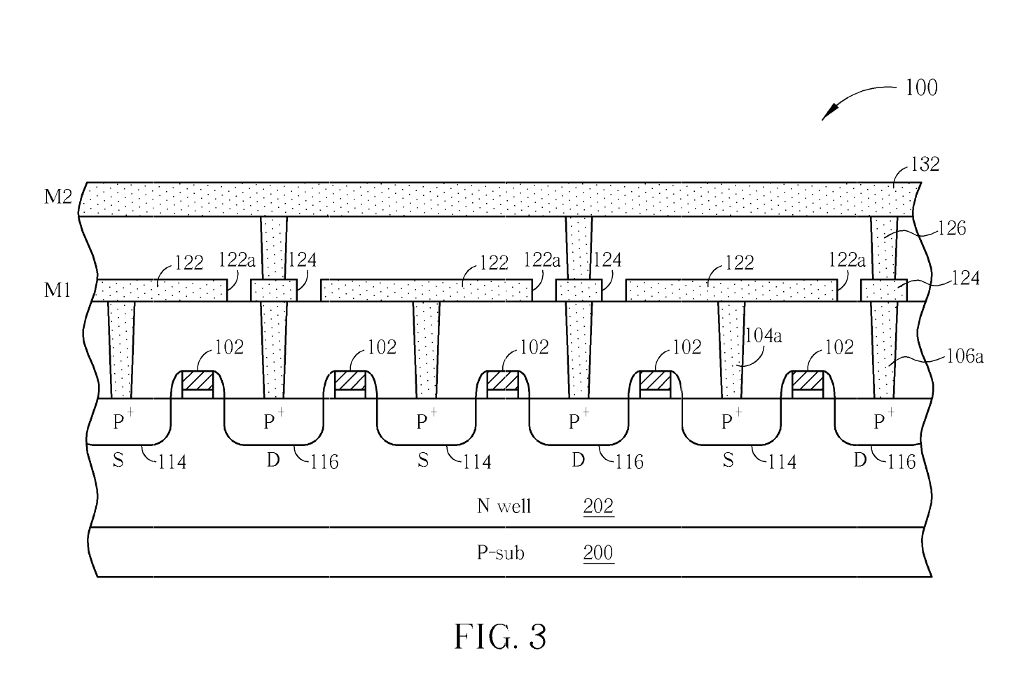

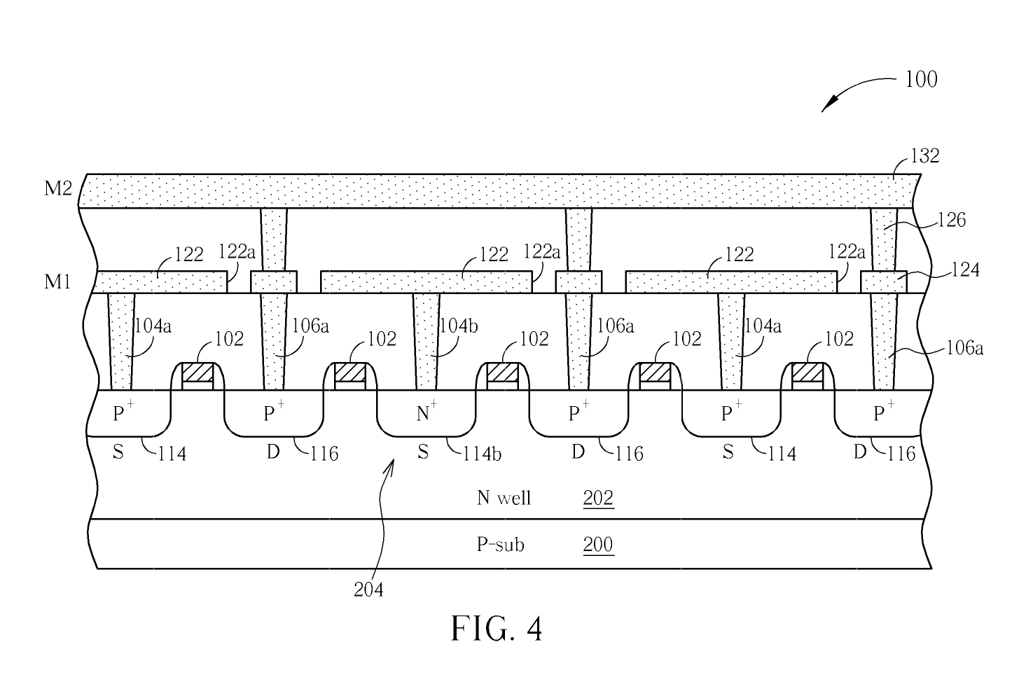

Please refer to FIGS. 2-4, wherein FIG. 2 is a partial layout diagram showing a waffle-type power MOS device in accordance with one embodiment of this invention, and FIGS. 3-4 are sectional views taken alone line I-I′ and II-II′ respectively in FIG. 2. As shown in FIGS. 2-4, according to the embodiment of this invention, the power MOS device 100 comprises a gate 102 with crosshatched lattice pattern on main surface of a substrate 200. The gate 102 surrounds each of the source regions 104 and each of the drain regions 106 separately, such that the gate 102, the source regions 104 and the drain regions 106 constitute an n×n transistor array. Each of the source regions 104 comprises a source diffusion region 114 of a first conductivity type, for example, a p+ source diffusion region, and each of the drain regions 106 comprises a drain diffusion region 116 of the first conductivity type, for example, P+ drain diffusion region. According to the preferred embodiment of the invention, the source diffusion region 114 and the drain diffusion region 116 may be formed in an ion well 202 such as an N well of the substrate 200. According to the preferred embodiment of the invention, the substrate 200 may be a silicon substrate or an epitaxial semiconductor substrate, but not limited thereto.

According to the preferred embodiment of the invention, as shown in FIG. 3, the source diffusion region 114 is electrically connected to an overlying source interconnection metal layer 122 via a source contact element or source contact plug 104a, and the drain diffusion region 116 is electrically connected to an overlying drain interconnection metal layer 132 via a drain contact element or drain contact plug 106a, metal pad 124 and via plug 126 by way of the aperture 122a in the source interconnection metal layer 122. As shown in FIG. 2, the gate 102 is electrically connected to an annular-shaped metal layer 121 at the peripheral region. A guard ring structure 118 may be provided to encompass the waffle-type power MOS device 100.

As shown in FIG. 3, each of the source regions 104, which is surrounded by the gate 102 with crosshatched lattice pattern, has only one diffusion region of the first conductivity type, and each of the drain regions 106, which is surrounded by the gate 102 with crosshatched lattice pattern, has only one diffusion region of the first conductivity type. Taking the PMOS transistor as an example, each of the source regions 104 can only have a P+ diffusion region and has no N type diffusion. Likewise, each of the drain regions 106 can only have a P+ diffusion region and has no N type diffusion. On the other hand, taking the NMOS transistor as an example, each of the source regions 104 can only have an N± diffusion region and has no P type diffusion. Likewise, each of the drain regions 106 can only have an N+ diffusion region and has no P type diffusion.

According to the preferred embodiment of the invention, the source diffusion regions 104 may be replaced with substrate contact diffusions 104b at some source sites across the transistor array. As shown in FIG. 4, and FIG. 2 briefly, taking the PMOS transistor as an example, at some specific source sites 204, substrate contact diffusion regions 114b of the second conductivity type such as N+ substrate contact diffusion regions are used to replace the P+ source diffusion region 114. These specific source sites 204 are selected and preserved for substrate contact or N well pick up. According to the preferred embodiment of the invention, each of the N+ substrate contact diffusion regions 114b is electrically connected to the overlying source interconnection metal layer 122 via the substrate contact plug 104b.

In accordance with the preferred embodiment of the invention, the substrate contact or N well pick up 204 is independent from the source region 104. The substrate contact or N well pick up 204 is disposed at the pre-selected, independent position separated by the gate 102. By doing this, the size and dimension of the unit transistor in the transistor array can be reduced and can depart from the limitation of the size of the source region 104. In accordance with the preferred embodiment of the invention, each of the source regions 104 or each of the drain regions 106 of the power MOS device 100 can have one single contact plug therein, whereby the size of each of the source regions 104 or each of the drain regions 106 can be minimized.

To sum up, it is advantageous to use the present invention power MOS device 100 because the substrate contact or N well pick up 204 is independent from the source region 104, whereby more transistors can be disposed within unit area, resulting in larger effective gate width and lower R_{DS(ON)}. However, it is to be understood that the present invention is not limited to the embodiment of single contact plug in each of the source regions 104 or drain regions 106. In another embodiment, multiple contact plugs may be disposed within each of the source regions 104 or drain regions 106. For example, two or four source contact plugs 104a may be disposed in each of the source regions 104 and two or four drain contact plugs 106a may be disposed within each of the drain regions 106.

Those skilled in the art will readily observe that numerous modifications and alterations of the device and method may be made while retaining the teachings of the invention.

What is claimed is:

1. A power MOS device comprising a substrate, a gate with crosshatched lattice pattern on a substrate, and at lease a source region and a drain region separated from each other by the gate, characterized in that the source region has only one diffusion region of a pre-selected conductivity type.

2. The power MOS device according to claim 1 wherein the diffusion region is a source diffusion region with a first conductivity type.

3. The power MOS device according to claim 2 wherein the drain region comprises a drain diffusion region of the first conductivity type.

4. The power MOS device according to claim 3 wherein the first conductivity type is P type.

5. The power MOS device according to claim 3 wherein the first conductivity type is N type.

6. The power MOS device according to claim 3 further comprising an ion well in the substrate, wherein the source diffusion region and the drain diffusion region are disposed in the ion well.

7. The power MOS device according to claim 1 wherein the diffusion region is a substrate contact diffusion region with a second conductivity type.

8. The power MOS device according to claim 7 wherein the second conductivity type is N type.

9. The power MOS device according to claim 7 wherein the second conductivity type is P type.

10. The power MOS device according to claim 1 wherein the source region has only one source contact plug.

11. The power MOS device according to claim 1 wherein the drain region has only one drain contact plug.
